(19) United States
(12) Patent Application Publication
(10) Pub. No.: US 2009/0127644 A1
(43) Pub. Date: May 21, 2009

(54) Semiconductor device comprising an image sensor, apparatus comprising such a semiconductor device and method of manufacturing such a semiconductor device

(75) Inventors: Anton Petrus Maria Van Arendonk, Waterloo (CA); Vic Pantea, Kitchener (CA); Brian Wayne Benwell, Waterloo (CA)

Correspondence Address: Fisher Technology Law, 40452 Hickory Ridge Place, Aldie, VA, 20105, US

(73) Assignees: Anton Petrus M. VAN ARENDONK; Vic PANTEA; Brian Wayne BENWELL

(21) Appl. No.: 11/985,788

(22) Filed: Nov. 16, 2007

(51) Int. Cl. H01L 31/0203; H01L 31/18

(52) U.S. Cl. 257/432; 438/65; 257/E31.127

(57) ABSTRACT

The invention relates to a semiconductor device comprising a semiconductor body in which an image sensor is formed and having a semiconductor body surface with an optically active part of the image sensor and a non-optically active part of the image sensor in which electrical connection areas of the image sensor are located, a spacer structure being present on the semiconductor body surface in the non-optically active part of the image sensor and an optical passive component being positioned on top of the spacer structure and above the image sensor and allowing radiation to impinge on the optically active part of the image sensor.

According to the invention the spacer structure is an open structure allowing the atmosphere above the optically active part of the image sensor to contact the atmosphere outside the spacer structure. The spacer structure may comprise a ring provided with at least one interruption and positioned around the optically active part of the image sensor. Preferably, the spacer structure comprises a plurality of dots.

### BACKGROUND OF THE INVENTION

The invention relates to a semiconductor device comprising a semiconductor body in which an image sensor is formed and having a semiconductor body surface with an optically active part of the image sensor and a non-optically active part of the image sensor in which electrical connection areas of the image sensor are located, a spacer structure being present on the semiconductor body surface in the non-optically active part of the image sensor and an optical passive component being positioned on top of the spacer structure and above the image sensor and allowing radiation to impinge on the optically active part of the image sensor. Such a semiconductor device may form a crucial component of a camera system. The image sensor may be either a CCD (=Charge Transfer Device) based device of the FT (=Frame Transfer) or so-called inter-line type. However, the sensor also may be a (C)MOS (=Complimentary Metal Oxide Semiconductor) device. The invention also relates to an apparatus, in particular a camera system, comprising such a device and to a method of manufacturing such a device.

A device of the kind mentioned in the opening paragraph is known from U.S. Pat. No. 5,074,683 to Tam et al. that has been issued on Dec. 24, 1991. In the known device (see FIG. 3) the spacer structure comprises a rectangular ring shaped structure which is positioned in the optically non-active part of the image sensor and around the optically active part of the image sensor. Above the image sensor and on top of the spacer structure an optically passive component in the form of a so-called FOP (=Fiber Optic Faceplate) is positioned and fixed. The FOP has a predetermined index of refraction fro passing light waves towards the active area of the sensor. The device with the FOP is mounted on a carrier, which also provides for electrical connection of the image sensor.

A disadvantage of the known device is that its manufacturing is not as cheap as possible, partly because the manufacturing yield is limited.

### SUMMARY OF THE INVENTION

The invention has for its object inter alia to provide a semiconductor device of the kind mentioned in the opening paragraph, which can be manufactured with a high yield, and in a cheap manner.

A semiconductor device according to the invention is characterized in that the spacer structure is an open structure allowing the atmosphere above the optically active part of the image sensor to contact the atmosphere outside the spacer structure. In this way, several problems are avoided that threaten the yield. Firstly, if now index-matching liquid is used within the spacer structure, out gassing of the material of the spacer structure may form a problem since such gasses are locked within the known spacer structure. Secondly, if such spacer structure is filled with an index matching liquid, similar locking problems can occur with said index matching liquid. By using an open spacer structure both gases and liquids (or gels) can leave the spacer structure and locking of such material is avoided.

A very simple way of obtaining the desired results is to provide an annular spacer structure like the prior art spacer structure with at least one interruption. Preferably however, such a ring structure is provided with a plurality of interruptions. In the most preferred embodiment the spacer structure comprises a plurality of dots. This offers very important additional advantages; apart from material saving an important manufacturing advantage is offered by the fact that the dots can be formed by a cheap and fast method like micro jetting.

Further surprising advantage are related to the specific nature of the device. The presence of a FOP easily damages the image sensor device reducing its manufacturing yield. If the spacer structure comprises dots, such damaging is much less likely to occur. The dots more easily cope with larger non-flatness both within the surface of the image sensor as in the surface of the FOP. In this way, the contact between image sensor and FOP is improved and the functioning of the dots as stress-releasing elements is improved as well. Due to a better stress-release damaging of the image sensor is avoided. In addition, the use of a plurality of dots offers a large freedom of design in the spacer structure. Due to a very limited size of the dots, they can be more easily and freely be positioned on the surface of the semiconductor body in the optically non-active part of the surface thereof, where however other passive semiconductor elements may be and in any case circuitry for operation and connection of the image sensor are present.

Preferably the dots have lateral size lying between 30 and 60 μm. The dots may be e.g. circular or rectangular in shape. The height of the dots is preferably in the range of 30 to 100 μm. A suitable number of dots may be in the range of 10 to 500. This holds e.g. for a semiconductor body having a size of 1000×1000 dm².

In a preferred embodiment the image sensor is positioned on and fixed to a carrier comprising further electrical connection areas that are electrically connected to the electrical connection areas of the image sensor. Preferably such a carrier is made of a metal like iron. This has the advantage of available cheap machining.

In a very favorable modification of the latter preferred embodiment a further semiconductor body comprising a further image sensor is positioned on and fixed to the carrier next to the semiconductor body with the image sensor while the spacer structure and the optically passive component extend above both the image sensor and the further image sensor. In particular in this embodiment, in which without the present invention, problems of un-flatness, non-planarity and unequal heights would be increased due to the presence of a plurality of semiconductor bodies, the present invention offers important advantages. A single FOP with a correspondingly increased size also contributes to the above problems. The spacer structure according to the present invention and of in particular this embodiment has the important additional function of relocating the mechanical stress due to problems with respect to co-planarity between the FOP and a multiple silicon device. In this way damages to the nodes and/or traces on the non-imaging part of the silicon are avoided in order to establish a better yield. Mechanical stress on these silicon parts can physically destroy the device or change or shift its electrical behavior. The above confirms that the present invention offers important advantages in that several problems leading to a reduction of the yield or a change of properties do not occur or at least are much likely to occur.

The spacer structure is preferably made of an organic material like a polymer. E.g. a thick photo-resist like SU-8 forms a suitable material. However, the dots can also be made of other soft materials like soft metals. A suitable example of the latter is Indium. Conducting materials do not form a problem as long as they are isolated with respect to the functionality of the device.

An important advantage of the embodiment in which the spacer structure comprises a plurality of dots is that these dots can be formed in a simple, cheap and fast manner. E.g. the technique of micro jetting may be advantageously be used for this purpose.

A method of manufacturing a semiconductor device comprising a semiconductor body in which an image sensor is formed and having a semiconductor body surface with an optically active part of the image sensor and a non-optically active part of the image sensor in which electrical connection areas of the image sensor are located, a spacer structure being formed on the semiconductor body surface in the non-optically active part of the image sensor and an optical passive component is positioned on top of the spacer structure and above the image sensor and allowing radiation to impinge on the optically active part of the image sensor, is according to the present invention, characterized in that the spacer structure is formed as an open structure allowing the atmosphere above the optically active part of the image sensor to contact the atmosphere outside the spacer structure. In this way, semiconductor devices according to the invention are obtained.

Preferably the spacer structure is formed as an annular structure around the optically active part of the image sensor which is provided with at least one interruption. In a more preferred embodiment the spacer structure is formed as a plurality of dots that are positioned at regular distances from each other around the optically active part of the image sensor.

### BRIEF DESCRIPTION OF THE DRAWINGS

These and other aspects of the invention will be apparent from and elucidated with reference to the embodiments described hereinafter, to be read in conjunction with the drawing, in which

FIG. 1 shows a diagrammatic, cross-sectional view along the line II-II of a plan view as in FIG. 2 of an embodiment of a semiconductor device in accordance with the invention FIG. 2 diagrammatically shows a plan view of a relevant part of the embodiment of device shown in cross-section in FIG. 1.

FIG. 3 through FIG. 7 show diagrammatic, cross-sectional views along the line II-II in FIG. 2 of several stages in the manufacture of the semiconductor device shown in cross-section in FIG. 1 by means of a method in accordance with the invention, and

The figures are diagrammatic and not drawn to scale, the dimensions in the thickness direction being particularly exaggerated for greater clarity. Corresponding parts are generally given the sane reference numerals and the same hatching in the various figures.

### DESCRIPTION OF THE PREFERRED EMBODIMENTS

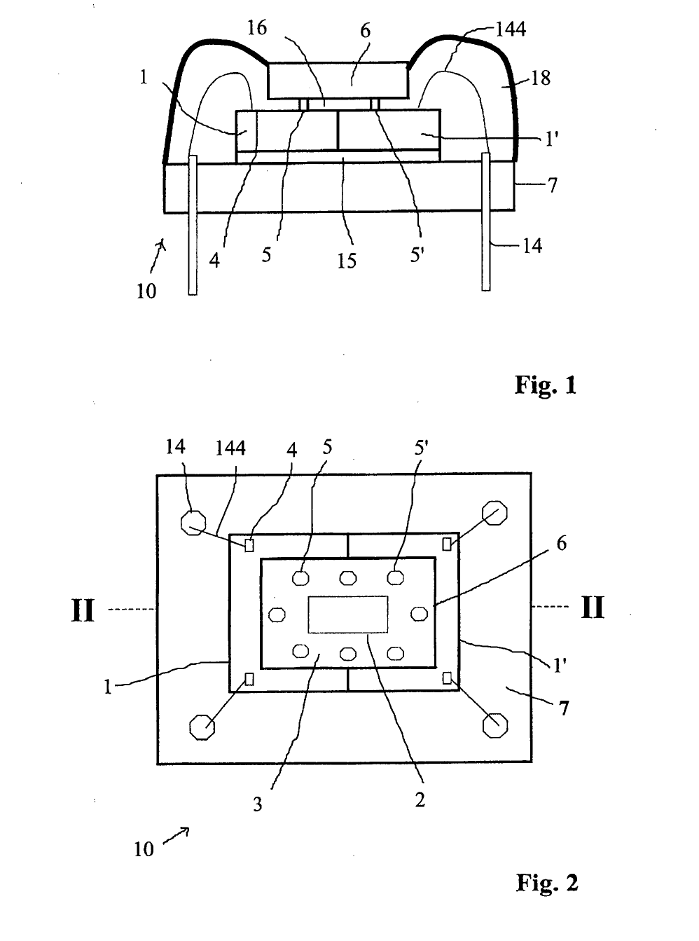

FIG. 1 shows a diagrammatic, cross-sectional view along the line II-II of a plan view as in FIG. 2 of an embodiment of a semiconductor device in accordance with the invention, and FIG. 2 diagrammatically shows a plan view of a relevant part of the embodiment of device shown in cross-section in FIG. 1. The device 10 comprises a carrier 7 made of Kovar (an Iron/Nickel alloy) which comprises electrically conducting pins 14, so-called PGA (=Pin Grid Array) pins, fixed in the carrier by means of a glass insulation. On the carrier 7 a die attach layer 15 is present by which a semiconductor body 1, in this example a plurality of semiconductor bodies 1, 1′, is attached to the carrier 7. The die attach layer 15 in this example is a layer of conductive epoxy and having a thickness of about 30-70 micron. The semiconductor bodies 1, 1′ comprise an image sensor and a further image sensor. These sensors are in this example of the CCD type and the size of the semiconductor bodies 1,1′ is about 13000×40000 square micron while the optically active areas are about 8000×40000 square micron.

As shown in FIG. 2, the optically active parts of the surface of the semiconductor bodies 1,1′ are within an area 2 while the remainder of said surface(s), which is not optically active is denoted as area 3. The latter area 3 comprises e.g. circuitry that is not shown in the drawing and contact pads 4. In this example a wire connection 114 electrically connects these pads 4 with pins 14.

In the optically inactive area 3 of the semiconductor bodies 1,1′ dots a spacer structure 5 is formed on the surface of the semiconductor bodies 1,1′ in the form of dots 5,5′ which are in this example formed of a photo resist material which is in this example a so-called SU-8 resist. The thickness of dots 5,5′ is here about 30-70 micron and the diameter of the about circular dots 5,5′ is near 40 micron. On top of the dots 5,5′ is a passive optical component 6 attached which comprises an FOP (=Fiber Optical Plate) device 6 in this example. The plate 6 allows radiation to impinge on the optically active area 2 of the image sensors 1,1′ and extends here also partially above the optically inactive area 3. The dots 5,5′ function here both as a spacer layer, a (weak) attachment of the plate 6 but also as stress deflectors for the stress that might be induced by the plate 6 into the semiconductor bodies 1,1′, in particular the very sensitive optically active areas of the image sensors formed in these semiconductor bodies 1,1′.

In this example between the dots 5,5′ an optical adhesive layer 16 is provided which functions as an index matching layer between the FOP plate 6 and the image sensors in the semiconductor bodies 1,1′ and also forms an attachment of the FOP plate 6 to the device 10. Here the optical adhesive layer 16 comprises an optical guide and has about the same thickness as the spacer dots 5,5′. The semiconductor device 10 of this example can be made as follows using a method of manufacturing according to the present invention.

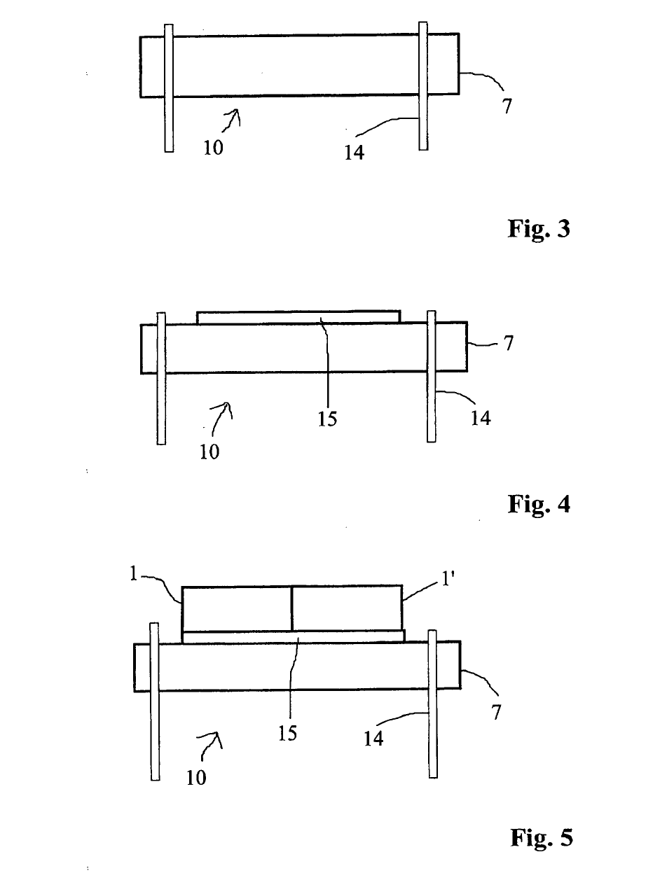

FIG. 3 through FIG. 7 show diagrammatic, cross-sectional views along the line II-II in FIG. 2 of several stages in the manufacture of the semiconductor device shown in cross-section in FIG. 1 by means of a method in accordance with the invention. Starting point is formed (see FIG. 3) by means of a Kovar carrier 7 having PGA pins 14. On said carrier 7 (see FIG. 4) a die attach layer is provided by means of a clear epoxy Material and thickness are selected as indicated above.

Next (see FIG. 5) semiconductor bodies 1,1′ comprising an image sensor and a further image sensor are attached to the carrier 7 by means of a die attach step.

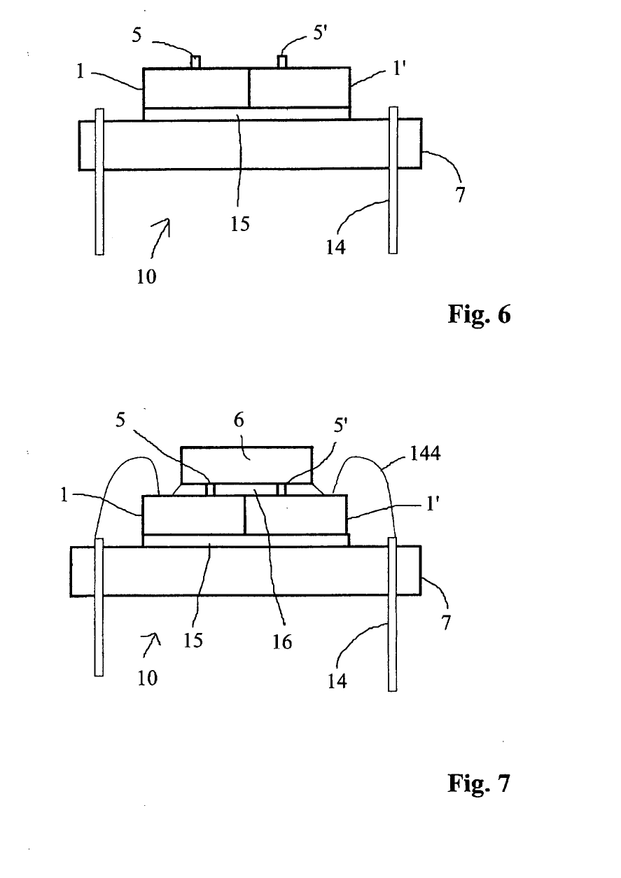

Subsequently (see FIG. 6) spacer dots 5,5′ are positioned on the surface of the semiconductor bodies 1,1′ outside the optically active surface area of the image sensors comprised within said bodies 1,1′. In this example the dots 5,5′ are deposited using a micro jetting technique and sizes and material of the dots 5,5′ are selected as indicated above.

Thereinafter (see FIG. 7) a wire connection 114 is formed between the electrical connection areas 4 of the semiconductor bodies 1,1′ and the pins 14. Forming these wire connections first has the advantage that a preliminary test can be applied to the sensors. In this way spending a FOP plate 6 to a faulty device can be avoided. Next, the FOP plate 6 is pressed onto and slightly attached to the spacer dots 5,5′. Then, an optically adhesive layer 16 can be applied between the surface of the semiconductor bodies 1,1′ and the FOP plate 6. Thank to the open nature of the spacer structure 5,5′ this layer can be formed after positioning of the FOP plate 6 since the liquid will fill the open space structure 5,5′ thanks to capillary forces. While in this examples the dots 5,5′ are formed on the semiconductor bodies 1,1′ it is also possible to deposited the dots 5,5′ onto the FOP plate 6 and to mount the latter with the dots 5,5′ onto the surface of the semiconductor bodies 1,1′.

Finally (see FIG. 1) an UV (=Ultra Violet) so-called Glop-Top encapsulation 18 is provided onto the device 10 for sealing and protecting the parts of the device outside the upper surface of the FOP plate 6. The device is know ready for use, e.g. in an apparatus like a camera system (not shown in the drawing) for e.g. dental, medical, industrial, or astronomic applications.

It will be obvious that the invention is not limited to the embodiment described here, but that many more variations are possible to those skilled in the art. Thus, by way of example, a description has been given of a CCD image sensor. It will be obvious, however, that the present invention can also advantageously be employed for other image sensors, such as for example (C)MOS (=(Complimentary) Metal Oxide Semiconductor) image sensors.

It is also possible to use alternative techniques, possibly in combination, for the different steps of the manufacturing.

1. A semiconductor device comprising a semiconductor body in which an image sensor is formed and having a semiconductor body surface with an optically active part of the image sensor and a non-optically active part of the image sensor in which electrical connection areas of the image sensor are located, a spacer structure being present on the semiconductor body surface in the non-optically active part of the image sensor and an optical passive component being positioned on top of the spacer structure and above the image sensor and allowing radiation to impinge on the optically active part of the image sensor, characterized in that the spacer structure is an open structure allowing the atmosphere above the optically active part of the image sensor to contact the atmosphere outside the spacer structure.

2. A semiconductor device as claimed in claim 1, characterized in that the spacer structure comprises an annular structure around the optically active part of the image sensor having at least one interruption.

3. A semiconductor device as claimed in claim 1, characterized in that the spacer structure comprises a plurality of dots positioned at regular distances from each other around the optically active part of the image sensor.

4. A semiconductor device as claimed in claim 3, characterized in that the number of dots lies between 10 and 500.

5. A semiconductor device as claimed in claim 1, characterized in that the semiconductor body with the image sensor is positioned on and fixed to a carrier comprising further electrical connection areas that are electrically connected to the electrical connection areas of the image sensor.

6. A semiconductor device as claimed in claim 5, characterized in that a further semiconductor body comprising a further image sensor is positioned on and fixed to the carrier next to the semiconductor body with the image sensor while the spacer structure and the optically passive component extend above both the image sensor and the further image sensor.

7. A semiconductor device as claimed in claim 1, characterized in that the spacer structure is formed of an organic material preferably a polymer.

8. A semiconductor device as claimed in claim 1, characterized in that the spacer structure is formed by micro jetting.

9. A semiconductor device as claimed in claim 1, characterized in that the spacer structure has a stress-releasing function in order to avoid damage of change of electrical properties in the non-optically active part of the image sensor.

10. An apparatus comprising a semiconductor device as claimed in claim 1.

11. A method of manufacturing a semiconductor device comprising a semiconductor body in which an image sensor is formed and having a semiconductor body surface with an optically active part of the image sensor and a non-optically active part of the image sensor in which electrical connection areas of the image sensor are located, a spacer structure being formed on the semiconductor body surface in the non-optically active part of the image sensor and an optical passive component is positioned on top of the spacer structure and above the image sensor and allowing radiation to impinge on the optically active part of the image sensor, characterized in that the spacer structure is formed as an open structure allowing the atmosphere above the optically active part of the image sensor to contact the atmosphere outside the spacer structure.

12. A method as claimed in claim 11, characterized in that the spacer structure is formed as an annular structure around the optically active part of the image sensor which is provided with at least one interruption.

13. A method as claimed in claim 11, characterized in that the spacer structure is formed as a plurality of dots that are positioned at regular distances from each other around the optically active part of the image sensor.

14. A method as claimed in claim 13, characterized in that the spacer structure is formed by micro jetting
